(19) United States
(12) Patent Application Publication
(10) Pub. No.: US 2015/0303373 A1
(43) Pub. Date: Oct. 22, 2015

(54) SPIN-TRANSFER SWITCHING MAGNETIC ELEMENT FORMED FROM FERRIMAGNETIC RARE-EARTH-TRANSITION-METAL (RE-TM) ALLOYS

(71) Applicant: QUALCOMM Incorporated, San Diego, CA (US)

(72) Inventors: Wei-Chuan CHEN, Taipei (TW); Xiaochun ZHU, San Diego, CA (US); Chando PARK, San Diego, CA (US); Seung Hyuk KANG, San Diego, CA (US)

(73) Assignee: QUALCOMM Incorporated, San Diego, CA (US)

(21) Appl. No.: 14/255,624

(22) Filed: Apr. 17, 2014

(51) Int. Cl. H01L 43/08; H01L 43/12; H01L 43/02; H01L 43/10

(52) U.S. Cl. CPC H01L 43/08; H01L 43/10; H01L 43/12; H01L 43/02

(57) ABSTRACT

A magnetic tunnel junction (MTJ) includes a free layer formed from a ferrimagnetic rare-earth-transition-metal (RE-TM) alloy having the net moment dominated by a sublattice moment of a rare-earth (RE) composition of the RE-TM alloy. The MTJ further includes a pinned layer formed from a rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

### FIELD OF DISCLOSURE

Disclosed embodiments are directed to spin-transfer switching magnetic tunnel junctions comprising free layers and pinned layers formed from combinations of ferrimagnetic rare earth (RE) rich materials and transition metal (TM) rich materials, with insertion layers formed from CoFeB, such that net magnetization is low and coercivity (Hc), magnetic anisotropy (Ku), and thermal stability are high.

### BACKGROUND

Magnetoresistive random access memory (MRAM) is a non-volatile memory technology that has response (read/write) times comparable to volatile memory. In contrast to conventional RAM technologies which store data as electric charges or current flows, MRAM uses magnetic elements. As illustrated in FIGS. 1A and 1B, a perpendicular magnetic tunnel junction (MTJ) storage element, MTJ 100, can be formed from two magnetic layers 110 and 130, each of which can hold a magnetic field, separated by an insulating (tunnel barrier) layer 120. One of the two layers (e.g., fixed or pinned layer 110), is set to a particular polarity. The other layer's (e.g., free layer 130) polarity 132 is free to change to match that of an external field that can be applied. A change in the polarity 132 of free layer 130 will change the resistance of MTJ 100. For example, when the polarities are aligned, FIG. 1A (parallel “P” magnetization low resistance state “0”), a low resistance state exists. When the polarities are not aligned, FIG. 1B (anti-parallel “AP” magnetization high resistance state “1”), then a high resistance state exists. The illustration of MTJ 100 has been simplified and those skilled in the art will appreciate that each layer illustrated may comprise one or more layers of materials.

Referring to FIG. 2, memory cell 200 of a conventional MRAM is illustrated for a read operation. Memory cell 200 includes transistor 210, bit line 220, digit line 230 and word line 240. Memory cell 200 can be read by measuring the electrical resistance of MTJ 100. For example, a particular MTJ 100 can be selected by activating an associated transistor 210 (transistor on), which can switch current from bit line 220 through MTJ 100. Due to the tunnel magnetoresistive effect, the electrical resistance of MTJ 100 changes based on the orientation of the polarities in the two magnetic layers (e.g., pinned layer 110 and free layer 130), as discussed above. The resistance inside any particular MTJ 100 can be determined from the current, resulting from the polarity of free layer 130. Conventionally, if pinned layer 110 and free layer 130 have the same polarity, the resistance is low and a “0” is read. If fixed layer 110 and pinned layer 130 have opposite polarity, the resistance is higher and a “1” is read.

Unlike conventional MRAM, perpendicular spin-transfer torque magnetoresistive random access memory (STT-MRAM) uses electrons that become spin-polarized as the electrons pass through a thin film (spin filter). STT-MRAM is also known as spin-transfer torque RAM (STT-RAM), spin torque transfer magnetization switching RAM (Spin-RAM), spin momentum transfer RAM (SMT-RAM), or simply, perpendicular spin-transfer switching magnetic element. During the write operation, the spin-polarized electrons exert a torque on a free layer, which can switch the polarity of the free layer. The read operation is similar to conventional MRAM in that a current is used to detect the resistance/logic state of the MTJ storage element, as discussed in the foregoing. As illustrated in FIG. 3A, STT-MRAM bit cell 300 includes MTJ 305, transistor 310, bit line 320 and word line 330. Transistor 310 is switched on for both read operations and write operations, to allow current to flow through the MTJ 305, so that the logic state can be read or written.

Referring to FIG. 3B, STT-MRAM bit cell 301 is illustrated with accompanying read/write circuitry. In addition to the previously discussed elements such as MTJ 305, transistor 310, bit line 320 and word line 330, a source line 340, sense amplifier 350, read/write circuitry 360 and bit line reference 370 are illustrated. As discussed above, during a read operation, a read current is generated, which flows between the bit line 320 and source line 340 through MTJ 305. When the current is permitted to flow via transistor 310, the resistance (logic state) of the MTJ 305 can be sensed based on the voltage differential between the bit line 320 and source line 340, which is compared to reference 370 and then amplified by sense amplifier 350.

With the above general construction and operation of perpendicular spin-transfer switching magnetic elements, such as MTJ 305 of STT-MRAM bit cells 300-301 in mind, several issues that are prevalent in the conventional structure of these MTJ storage elements are discussed as follows. Conventionally, free layer 130 of a MTJ 305 is formed from materials such as CoFeB, with thickness of around 10-15 A in current device technologies. However, CoFeB displays undesirable characteristics such as, low tunnel magnetic resistance (TMR), low magnetic anisotropy (Ku), and poor thermal stability. Some conventional free layers are formed from a Co-based multilayer in an attempt to improve the above characteristics. However, for such Co-based multilayers, it is seen that controlling process variation to achieve the desired composition of the multilayers is difficult. Moreover, such multilayer constructions of free layers also suffer from characteristics such as, high current density (Jc), high saturation magnetization (Ms), high damping constant, etc. Similar issues are seen for free layers which are formed from alloys such as, CoFeB/L10 alloy or FePt. Such alloys require a high temperature process for formation; the process of deposition of films for the MTJ is very difficult at high temperatures. Further, such alloys also suffer from characteristics such as, high current density (Jc), high saturation magnetization (Ms), high damping constant, etc.

Similar to the difficulties seen above with regard to conventional free layers, construction of conventional pinned layers, such as, pinned layer 110 also suffers from several undesirable properties. Pinned layers are also conventionally formed from materials such as CoFeB, with thickness of around 10-12 A in current device technologies. As previously, CoFeB displays undesirable characteristics such as, low tunnel magnetic resistance (TMR), low magnetic anisotropy (Ku), and poor thermal stability. It is also seen to be difficult to control variation of properties of MTJs whose pinned layers are formed CoFeB; large stray fields are observed. Some conventional pinned layers are formed from Co-based synthetic antiferromagnetic (SAF) multilayers, which have a complicated structure; the off-set field for such pinned layers tends to be unbalanced, and they display low TMR. For pinned layers constructed from L10-alloys or FePt alloys, once again high temperature processes required for formation of such alloys creates difficulties in the formation of the pinned layer and the MTJ.

Accordingly, there is a need in the art for efficient designs of perpendicular spin-transfer switching magnetic elements which avoid the aforementioned problems.

### SUMMARY

Exemplary embodiments are directed to magnetic tunnel junction (MTJ) which includes a free layer formed from a ferrimagnetic rare-earth-transition-metal (RE-TM) alloy having the net moment dominated by a sublattice moment of a rare-earth (RE) composition of the RE-TM alloy. The MTJ further includes a pinned layer formed from a ferrimagnetic rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

For example, an exemplary embodiment is directed to a magnetic tunnel junction (MTJ) comprising: a free layer formed from a rare-earth-transition-metal (RE-TM) alloy having the net moment dominated by a sublattice moment of a rare-earth (RE) composition of the RE-TM alloy; and a pinned layer formed from a rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

Another exemplary embodiment is directed to a magnetic tunnel junction (MTJ) comprising: a pinned layer, the pinned layer comprising: a first layer comprising a rare-earth-transition-metal (RE-TM) alloy having the net moment dominated by a sublattice moment of a rare-earth (RE) composition of the RE-TM alloy; and a second layer comprising rare-earth-transition-metal (RE-TM) alloy having the net moment dominated by a sublattice moment of a transition-metal (TM) composition of the RE-TM alloy. A thin CoFeB, Fe-based or Co-based layer is formed between the first layer and the second layer to provide interlayer coupling between the first layer and the second layer, wherein the net magnetic moment of the pinned layer is low or equal to zero.

Yet another exemplary embodiment is directed to a method of forming a magnetic tunnel junction (MTJ), the method comprising: forming a free layer from a rare-earth-transition-metal (RE-TM) alloy having the net moment dominated by a sublattice moment of a rare-earth (RE) composition of the RE-TM alloy; and forming a pinned layer formed from a rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

Yet another exemplary embodiment is directed to a method of forming a magnetic tunnel junction (MTJ), the method comprising: forming a pinned layer comprising: forming a first layer comprising a rare-earth-transition-metal (RE-TM) alloy having the net moment dominated by a sublattice moment of a rare-earth (RE) composition of the RE-TM alloy and forming a second layer comprising rare-earth-transition-metal (RE-TM) alloy having the net moment dominated by a sublattice moment of a transition-metal (TM) composition of the RE-TM alloy. The method further comprises forming a thin CoFeB, Fe-based or Co-based layer between the first layer and the second layer to provide interlayer coupling between the first layer and the second layer, wherein the net magnetic moment of the pinned layer is low or equal to zero.

### BRIEF DESCRIPTION OF THE DRAWINGS

The accompanying drawings are presented to aid in the description of embodiments of the various embodiments and are provided solely for illustration of the embodiments and not limitation thereof.

FIGS. 1A and 1B are illustrations of a magnetic tunnel junction (MTJ) storage element.

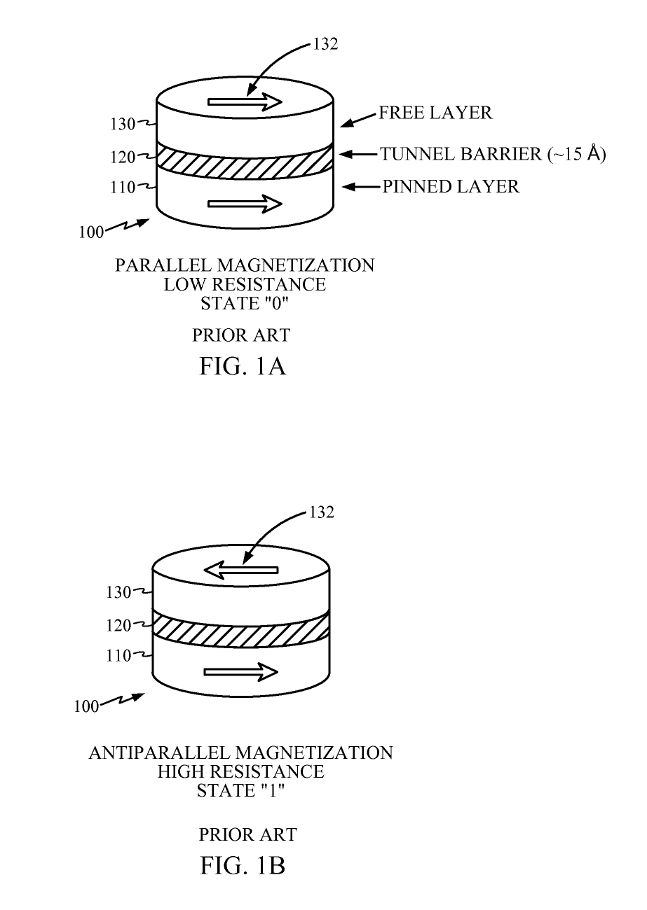

FIG. 2 is an illustration of a Magnetoresistive Random Access Memory (MRAM) cell during read operations.

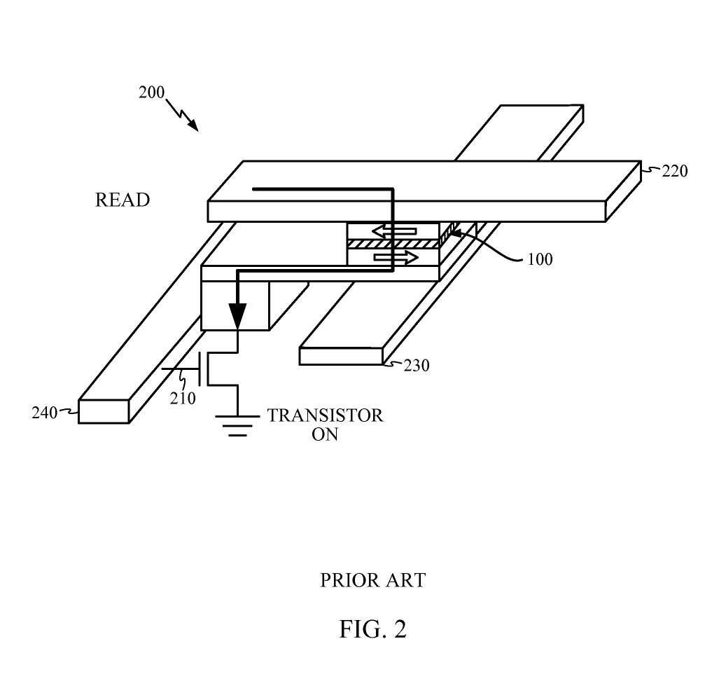

FIGS. 3A and 3B are illustrations of Spin-transfer Torque Magnetoresistive Random Access Memory (STT-MRAM) cells.

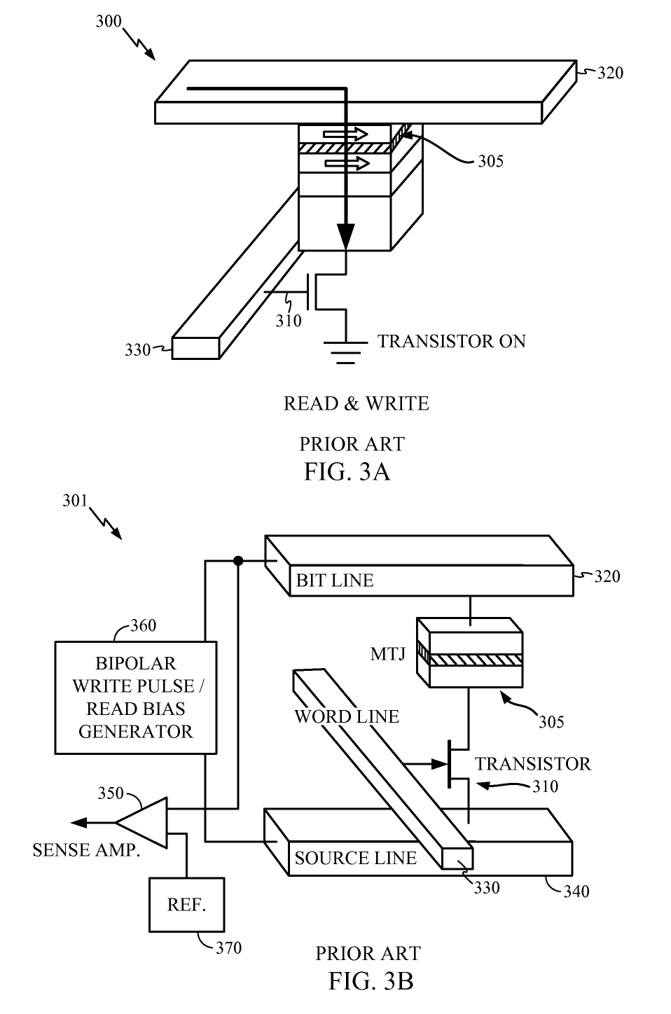

FIG. 4 is a graphical illustration of the relationship between coercivity Hc and magnetization M as a function of temperature for RE-rich and TM-rich materials.

FIG. 5 illustrates an exemplary spin-transfer switching magnetic element including a RE-rich RE-TM material free layer.

FIG. 6 illustrates an exemplary spin-transfer switching magnetic element including a RE-rich RE-TM material free layer and a RE-rich RE-TM material pinned layer.

FIG. 7 is a graphical illustration a relationship between coercivity Hc and magnetization M, as a function of RE composition in a RE-TM combination material.

FIG. 8 illustrates an exemplary spin-transfer switching magnetic element including a RE-rich RE-TM material free layer, and a composite pinned layer formed from a TM-rich RE-TM material layer and a RE-rich RE-TM material layer.

FIG. 9 illustrates a flow diagram for a method of forming an exemplary MTJ according to aspects of this disclosure.

### DETAILED DESCRIPTION

Aspects of the various embodiments are disclosed in the following description and related drawings directed to specific embodiments. Alternate embodiments may be devised without departing from the scope of the invention. Additionally, well-known elements of the various embodiments will not be described in detail or will be omitted so as not to obscure the relevant details of the various embodiments.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments include the discussed feature, advantage or mode of operation.

The terminology used herein is for the purpose of describing particular embodiments only and is not intended to be limiting of embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Exemplary embodiments overcome the problems associated with conventional free layer and pinned layer constructions in magnetic tunnel junctions, with formations which utilize ferrimagnetic rare-earth-transition-metal alloys (or “RE-TM alloys” or “RE-TM composition”). In general, exemplary embodiments recognize that controlling the composition of rare earth (RE) and transition metal (TM) materials in the formation of the free and pinned layers of an MTJ can overcome the numerous drawbacks of conventional free and pinned layers discussed above. As used herein, the term “RE-rich” conveys that the sublattice moment of RE material in a RE-TM alloy is larger than that of TM material in the RE-TM alloy. In other words, “RE-rich” indicates that the net moment or magnetization of the RE-TM alloy is dominated by the magnetic moment of the RE composition. The term “RE-rich” does not necessarily convey that content (e.g., by weight, volume, amount, etc.,) of RE material is higher than the content of TM material in the RE-TM alloy. Similarly, the term “TM-rich” conveys that the sublattice moment of TM material in an RE-TM alloy is larger than that of RE material in the RE-TM alloy. In other words, “TM-rich” indicates that the net moment or magnetization of the RE-TM alloy is dominated by the magnetic moment of the TM composition. The term “TM-rich” does not necessarily convey that content (e.g., by weight, volume, amount, etc.,) of TM material is higher than the content of RE material in the RE-TM alloy.

Specifically, it is seen that for an exemplary free layer, a RE-rich composition, with a RE-rich RE-TM alloys can lead to high coercivity (Hc) at operating temperature, which leads to good retention of the value stored in the MTJ cell. The RE-rich composition leads to overall low magnetic moment or saturation magnetization (Ms) based on the balancing out the contribution from the TM elements. Thus, a RE-rich composition, with a RE-TM alloy or free layer, such as GdFeCo, GdCo or GdFe, leads to high magnetic anisotropy (Ku), low Ms (which also implies low current density (Jc)) as well as, high coercivity (Hc).

Similarly, an exemplary pinned layer can be formed from a RE-TM alloy which is a RE-rich composition, thus displaying characteristics of high Hc, high Ku, and low Ms. Such materials which can be used in the formation of exemplary pinned layers can include TbFeCo or TbFe. Accordingly, exemplary embodiments display a desirable characteristic of maintaining the net Ms of the exemplary pinned layer to be nearly or equal to zero.

In some aspects, exemplary embodiments also comprise a thin CoFeB, FeB, Fe or Fe-based alloy layer inserted in the pinned layer to control the Ms. Additionally, a few thin Ta layers or doping elements (e.g., Boron (B)) can be inserted in the pinned layer in order to enhance crystallization temperature.

Additionally, in some aspects, MTJ cells can be formed with free layer and pinned layer constructions designed to provide a net Ms of nearly or equal to zero. For example, an exemplary perpendicular MTJ cell can comprise a free layer formed from a RE-TM composition which is RE-rich; and a multilayer pinned layer, significantly formed from two segments—a top segment (i.e., closest to the barrier layer separating the pinned layer from the free layer) which is TM-rich, and thus configured to provide high Ku, and high TMR, and a bottom segment which is RE-rich to provide high Ku at high temperature and compensate for the overall Ms of the pinned layer (i.e., including the top RE-rich and bottom TM-rich segments together) to be zero. Some exemplary aspects can also include a thin ferromagnetic layer (e.g., CoFeB, FeB, Fe or Fe-based alloy) layer, formed in between the top and bottom segments, in order to provide interlayer coupling layer between the top and bottom and segments.

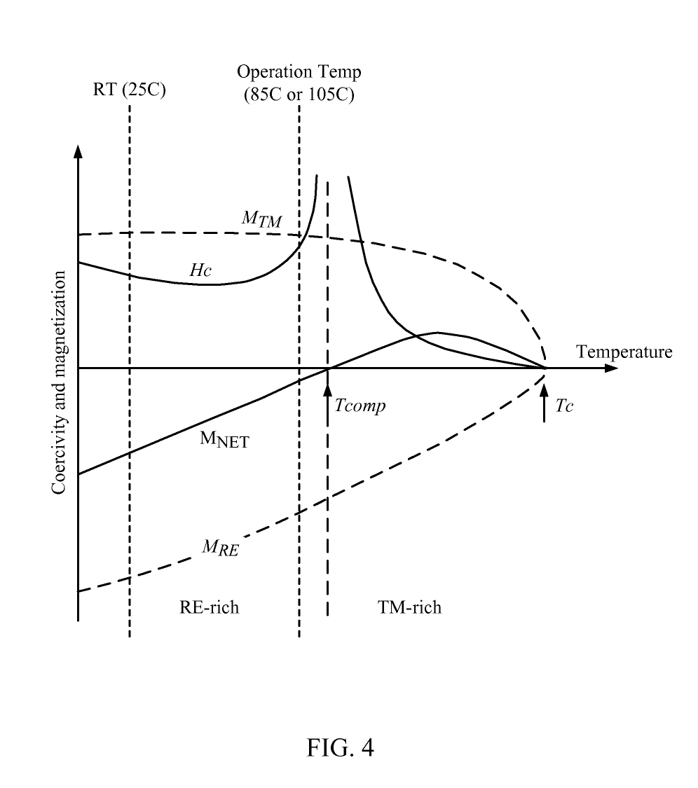

With reference to FIG. 4, a graphical illustration is provided for the relationship between coercivity Hc and magnetization M as a function of temperature for RE-TM with RE-rich and with TM-rich materials. M_{TM} represents the sublattice moment of transition metal (TM), whereas M_{RE} represents the sublattice moment of rare earth (RE). M_{NET} represents net magnetization of a composition of RE-TM materials. As seen, starting from room temperature (RT 25 C), He rises as temperature increases to an operating temperature of around 85-105 C for RE-TM with RE-rich materials. On the other hand, for RE-TM with TM-rich materials, He tends to fall towards zero as temperature increases to a Curie temperature (Tc). Further, the sublattice moment between RE (M_{RE}) and TM (M_{TM}) of RE-TM materials is an antiferromagnetic coupling. Therefore, the net moment (Mnet) of RE-TM materials will be zero at Tc. Accordingly, exemplary embodiments can be configured to provide a net magnetization of zero for exemplary MTJ bit cells by varying the composition of RE-TM alloys, even at high temperatures.

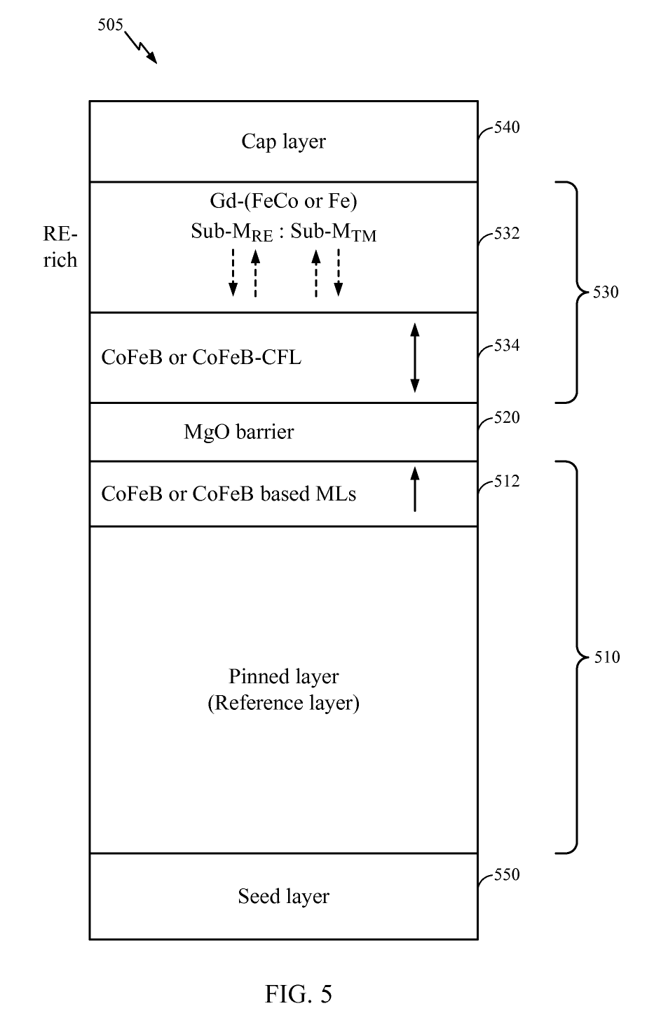

With reference to FIG. 5, an exemplary spin-transfer switching magnetic element including MTJ 505 is illustrated. MTJ 505 comprise pinned layer 510, MgO barrier or barrier layer 520, and free layer 530. More specifically, pinned layer 510 may be a multilayer which includes a CoFeB or Fe-based multilayer 512. Free layer 530 is a composite layer, with a RE-rich GdFeCo or GdFe layer 532 and a single CoFeB or CoFeB-based multilayer 534. Free layer 530 displays the above-described advantageous characteristics of high Ku and low Ms. The thickness and composition of RE-rich Gd—FeCo or GdFe layer 532 can be tuned to adjust the Ku and Ms of free layer 530. The CoFeB layer 534 can enhance tunneling magnetoresistance (TMR) of free layer 530, and the CoFeB layer 534 also serves for coupling sub-lattice moment of TM elements FeCo or Fe of the RE-TM GdFeCo or GdFe layer 532. The net magnetization of the CoFeB-based free layer 530 with the RE-TM GdFeCo layer will be very small (or close to zero) due to magnetization compensation between the RE-sublattice moment and the TM-sublattice moment. The He at operation temperature is higher than He at room temperature, as seen from FIG. 4, which leads to good retention capabilities of MTJ 505. Optionally, MTJ 505 may also include seed layer 550 on which pinned layer 510 is formed, and cap layer 540 formed on top of free layer 530.

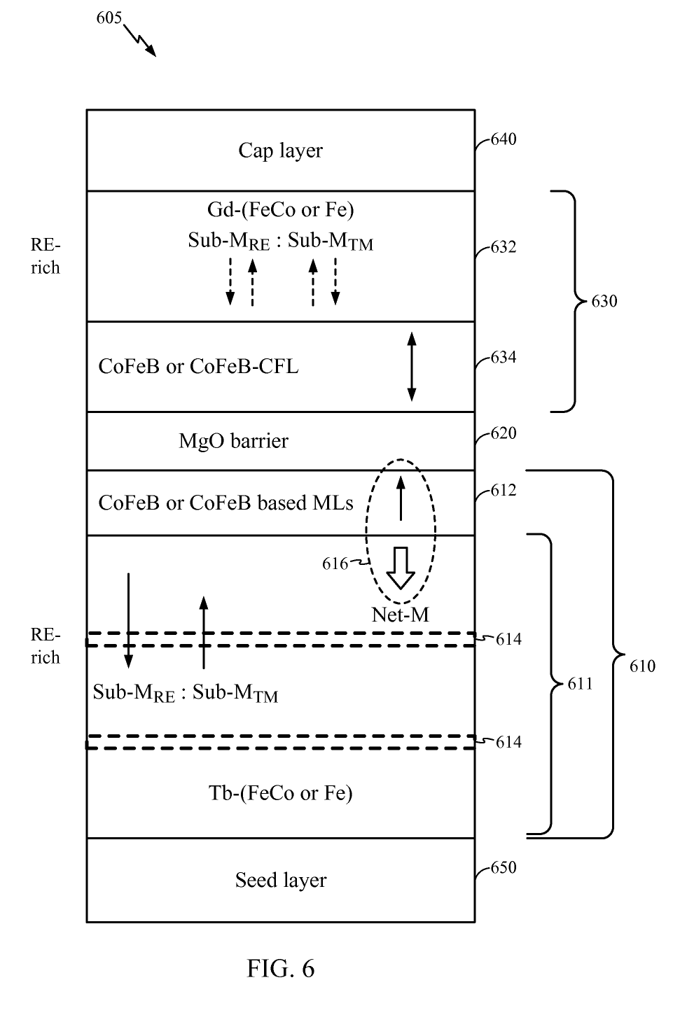

With reference to FIG. 6, another exemplary spin-transfer switching magnetic element including MTJ 605 is illustrated. In addition to the RE-rich free layer 630, similar to free layer 530 described in MTJ 505 of FIG. 5, MTJ 605 also includes pinned layer 610, which is a composite pinned layer comprising an RE-rich RE-TM layer 611 (e.g. made of TbFeCo or TbFe) and a CoFeB or Fe-based insertion layer 612. More specifically, once again, free layer 630 may a composite layer, with a RE-rich GdFeCo or GdFe layer 632 and may comprise a single CoFeB layer or CoFeB-based multilayers 634. Free layer 630 displays the above-described advantageous characteristics of high Ku and low Ms.

As noted, pinned layer 610 is a multilayer which includes the CoFeB or Fe-based insertion layer 612 and the RE-TM with RE-rich layer 611. The RE-TM with RE-rich layer 611 can further comprise one or more amorphous thin insertion layers 614, wherein amorphous thin insertion layers 614 can comprise one or more layers of Tantalum (Ta), Tantalum (TaN), Titanium (Ti), Titanium-Nitride (TiN), Boron (B), or any combination thereof. These amorphous thin insertion layers 614 may advantageously enhance crystallization temperature Tc in the order of >400 C for the microstructure of pinned layer 610.

With continuing reference to FIG. 6, the illustrated marker 616 indicates that with the combination of the magnetic moment of CoFeB or Fe-based insertion layer 612 and the net moment of RE-TM with RE-rich layer 611, the net magnetization or magnetic moment (Net-M) of pinned layer 610 is nearly or equal to zero. In order to bring the net moment of pinned layer 610 as close to zero as possible, the thickness of the CoFeB or Fe-based insertion layer 612 and/or the composition of the RE-TM with RE-rich layer 611 can be adjusted. Instead of CoFeB or Fe-based materials, it is also possible to use TbFeCo in multilayer 612.

It will also be noted that MgO barrier layer 620 is provided between free layer 630 and pinned layer 610, where, optionally, MTJ 605 may also include seed layer 650 on which pinned layer 610 is formed, and cap layer 640 formed on top of free layer 630.

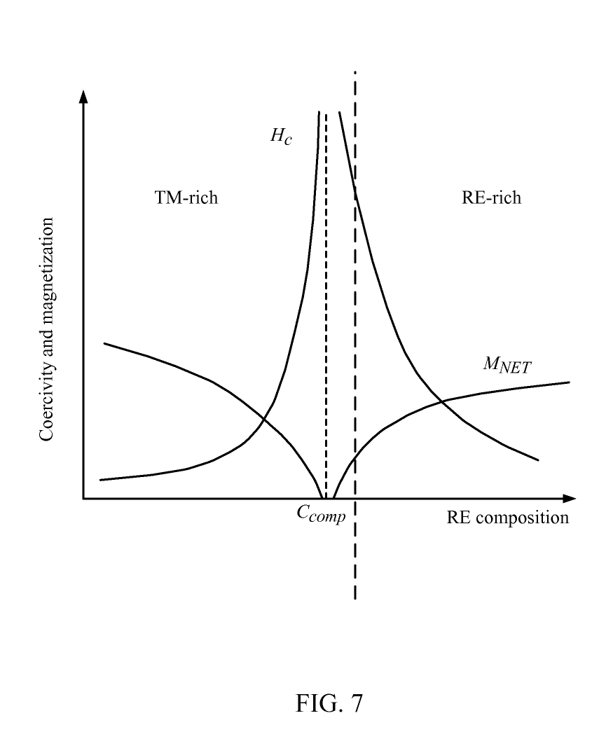

With reference to FIG. 7, a graphical illustration of coercivity Hc and magnetization of a layer, such as, the aspects of pinned layer 610 related to layer 611 of FIG. 6 is illustrated, as a function of RE composition in a RE-TM alloy material. As the amount of TM elements decrease, or in other words, the composition of RE elements increase from zero to a composition compensation point (illustrated as C_{comp}), Hc increases and the net magnetic moment (M_{NET}) decreases. Beyond the C_{comp} point, Hc starts to decrease and M_{NET} tends to increase as the RE composition increases. Thus, the composition of RE-TM alloy pinned layers are adjusted, such that the RE composition is close to C_{comp} in order to achieve favorable characteristics such as zero M_{NET} and high Hc.

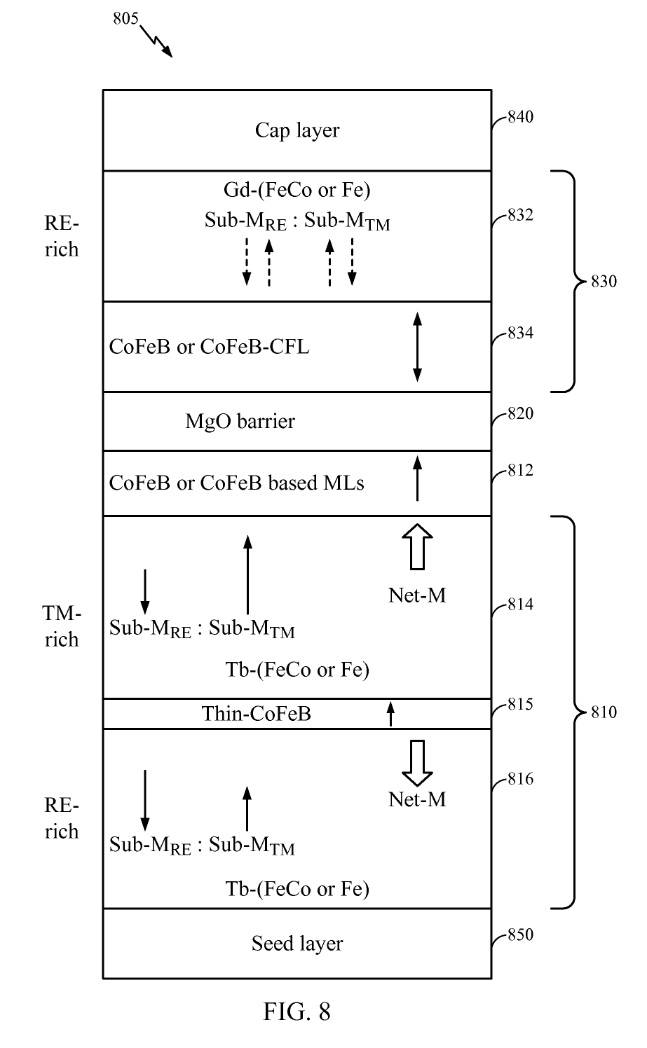

With reference to FIG. 8, another exemplary spin-transfer switching magnetic element including MTJ 805 is illustrated. Once again, free layer 830 is a composite layer, similar to free layers 530 and 630 described in MTJs 505 and 605 of FIGS. 5-6 respectively. More specifically, once again, free layer 830 includes a RE-rich GdFeCo or GdFe layer 832 and may further include a single CoFeB or Fe-based multilayers 834. Free layer 830 also displays the above-described advantageous characteristics of high Ku and low Ms.

With regard to pinned layer 810, in order to bring the net magnetization to zero, complementary segments comprising a first layer formed from a RE-rich RE-TM layer 816 and a second layer formed from a TM-rich RE-TM segment or layer 814 are provided. A thin CoFeB, Fe-based, or Co-based layer 815 formed in between the first layer (RE-rich RE-TM layer 816) and the second layer (TM-rich RE-TM layer 814) serves to provide interlayer coupling layer between the first and second layers, RE-rich RE-TM layer 816 and TM-rich RE-TM layer 814, respectively.

In some aspects, TM-rich RE-TM layer 814 has characteristics of high Ku and high TMR due to the high content of TM materials, while RE-rich layer 816 displays characteristics of high Ku at high temperature and compensate for the opposite magnetization of TM-rich layer 814, in order to bring the overall Ms of pinned layer 810 very close to zero. TbFeCo or TbFe can be used for forming TM-rich RE-TM layer 814 as well as RE-rich RE-TM layer 816. A coFeB or Fe-based multilayer 812 can also be provided on top of TM-rich RE-TM layer 814. It will also be noted that MgO barrier layer 820 is provided between free layer 830 and pinned layer 810, where, optionally, MTJ 805 may also include seed layer 850 on which pinned layer 810 is formed, and cap layer 840 formed on top of free layer 830.

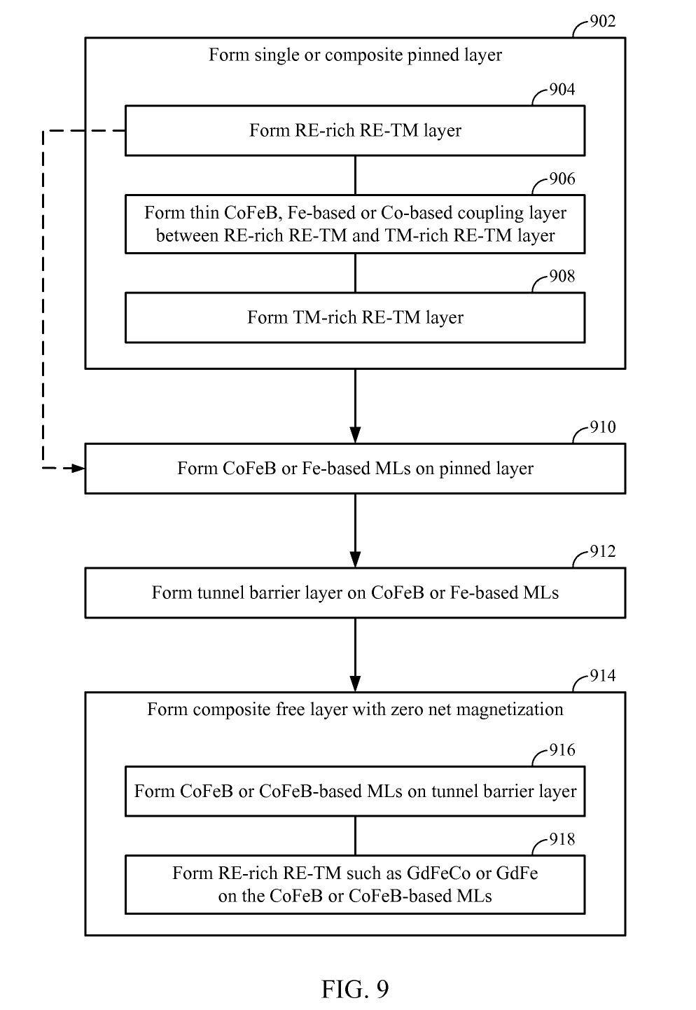

It will be appreciated that embodiments include various methods for performing the processes, functions and/or algorithms disclosed herein. For example, as illustrated in FIG. 9, an embodiment can include a method of forming a perpendicular STT-MRAM or exemplary magnetic tunnel junction (MTJ), the method comprising: forming a pinned layer—Block 902—wherein the pinned layer may be a single layer or a composite pinned layer (e.g., pinned layer 810). Accordingly, Block 902 may further comprise optional sub-blocks pertaining to forming an RE-rich RE-TM layer (e.g., 816)—Block 904; forming a thin CoFeB, Fe-based, or Co-based coupling layer (e.g., 815)—Block 906 and forming a TM-rich RE-TM layer (e.g., 814) such that the coupling layer (815) is formed between the RE-rich RE-TM layer (816) and the TM-rich RE-TM layer (814)—Block 908.

Once the single or composite pinned layers are formed in Block 902 (which may further comprise Blocks 904-908 above), the method can comprise forming one or more CoFeB or Fe-based multilayers (e.g., 812) on the pinned layer—Block 910; and forming a tunneling barrier or MgO layer (e.g., 820) on the CoFeB or Fe-based multilayers (812). It will also be noticed, that as indicated by the dashed line, in some alternative aspects, Blocks 906-908 may be omitted, wherein, once the RE-rich RE-TM layer is formed in Block 904, the method may proceed directly to Block 910.

The method can further comprise forming a composite free layer (e.g., 830)—Block 914. Block 914 may also additionally comprise forming CoFeB or CoFeB-based multilayers (e.g., 834) on the tunnel barrier layer—Block 916; and forming RE-rich RE-TM (e.g., RE-rich GdFeCo or GdFe layer 832) on CoFeB or CoFeB-based multilayers—Block 918.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for forming a perpendicular STT-MRAM with a combination of RE and TM materials. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

1. A magnetic tunnel junction (MTJ) comprising:
a free layer formed from a rare-earth-transition-metal (RE-TM) alloy having the net moment dominated by a sublattice moment of a rare-earth (RE) composition of the RE-TM alloy; and
a pinned layer formed from a rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

2. The MTJ of claim 1, further comprising a barrier layer between the free layer and the pinned layer.

3. The MTJ of claim 2, wherein the free layer further comprises a single CoFeB layer or CoFeB-based multilayers formed between the barrier layer and the RE-TM alloy having the net moment dominated by a sublattice moment of the RE composition of the RE-TM alloy.

4. The MTJ of claim 1, wherein the pinned layer further comprises a CoFeB-based or Fe-based insertion layer.

5. The MTJ of claim 1 wherein the free layer and pinned layer are formed from materials comprising TbFeCo, TbFe, GdFeCo, GdFe, or GdCo.

6. The MTJ of claim 1, wherein the one or more amorphous thin insertion layers comprise one or more layers of Tantalum (Ta), Tantalum (TaN), Titanium (Ti), Titanium-Nitride (TiN), Boron (B), or any combination thereof.

7. A magnetic tunnel junction (MTJ) comprising:
a pinned layer, the pinned layer comprising:
a first layer comprising a rare-earth-transition-metal (RE-TM) alloy having the net moment dominated by a sublattice moment of a rare-earth (RE) composition of the RE-TM alloy;
a second layer comprising rare-earth-transition-metal (RE-TM) alloy having the net moment dominated by a sublattice moment of a transition-metal (TM) composition of the RE-TM alloy, and
a thin CoFeB, Fe-based or Co-based layer formed between the first layer and the second layer to provide interlayer coupling between the first layer and the second layer, wherein the net magnetic moment of the pinned layer is low or equal to zero.

8. The MTJ of claim 7 further comprising a free layer formed from a rare-earth-transition-metal (RE-TM) alloy having the net moment dominated by a sublattice moment of a rare-earth (RE) composition of the RE-TM alloy.

9. The MTJ of claim 8, wherein the free layer further comprises a single CoFeB layer or CoFeB-based multilayers.

10. A method of forming a magnetic tunnel junction (MTJ), the method comprising:
forming a free layer from a rare-earth-transition-metal (RE-TM) alloy having the net moment dominated by a sublattice moment of a rare-earth (RE) composition of the RE-TM alloy; and
forming a pinned layer formed from a rare-earth-transition-metal (RE-TM) alloy having the net moment dominated by a sublattice moment of a rare-earth (RE) composition of the RE-TM alloy, the pinned layer comprising one or more amorphous thin insertion layers such that a net magnetic moment of the free layer and the pinned layer is low or close to zero.

11. The method of claim 10, further comprising forming a barrier layer between the free layer and the pinned layer.

12. The method of claim 11, further comprising forming the free layer from a single CoFeB layer or CoFeB-based multilayers.

13. The method of claim 10, further comprising forming a CoFeB-based or Fe-based insertion layer in the pinned layer.

14. The method of claim 10 further comprising forming the free layer and pinned layer are from materials comprising TbFeCo, TbFe, GdFeCo, or GdCo.

15. The method of claim 10, comprising forming the one or more amorphous thin insertion layers from one or more layers of Tantalum (Ta), Tantalum (TaN), Titanium (Ti), Titanium-Nitride (TiN), Boron (B), or any combination thereof.

16. A method of forming a magnetic tunnel junction (MTJ), the method comprising:
forming a pinned layer comprising:
forming a first layer comprising a rare-earth-transition-metal (RE-TM) alloy having the net moment dominated by a sublattice moment of a rare-earth (RE) composition of the RE-TM alloy;
forming a second layer comprising rare-earth-transition-metal (RE-TM) alloy having the net moment dominated by a sublattice moment of a transition-metal (TM) composition of the RE-TM alloy, and
forming a thin CoFeB, Fe-based or Co-based layer between the first layer and the second layer to provide interlayer coupling between the first layer and the second layer, wherein the net magnetic moment of the pinned layer is low or equal to zero.

17. The method of claim 16, further comprising forming a free layer from a rare-earth-transition-metal (RE-TM) alloy having the net moment dominated by a sublattice moment of a rare-earth (RE) composition of the RE-TM alloy.

18. The method of claim 17, forming a single CoFeB layer or CoFeB-based multilayers in the free layer.
